(19) United States
(12) Patent Application Publication
(10) Pub. No.: US 2006/0017455 A1
(43) Pub. Date: Jan. 26, 2006

(54) Defect diagnosis method and apparatus for semiconductor integrated circuit

(76) Inventors: Shuji Kikuchi, Yokohama (JP); Yasumaro Komiya, Yokohama (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/151,263

(22) Filed: Jun. 14, 2005

(30) Foreign Application Priority Data
Jun. 16, 2004 (JP) 2004-177744

(51) Int. Cl. G01R 31/26

(52) U.S. Cl. 324/765

(57) ABSTRACT

In a method of diagnosing a defect of a semiconductor integrated circuit by locally applying an electric field (magnetic field) by using a probe to a surface of the semiconductor integrated circuit and thereby detecting a fluctuation of electric characteristics, such as power supply current, in the semiconductor integrated circuit with respect to the surface. A position reference is provided in the semiconductor integrated circuit and, when diagnosing it, a position of the probe is aligned to this position reference and the local electric field (magnetic field) is applied from the probe to a specified position of an internal coordinate of the semiconductor integrated circuit.

The present application claims priority from Japanese application JP 2004-177744 filed on Jun. 16, 2004, the content of which is hereby incorporated by reference into this application.

### BACKGROUND OF THE INVENTION

1. Field of the Invention

The present invention relates to a defect diagnosis method for a semiconductor and a defect diagnosis apparatus for the same, in each of which it is a purpose to detect an existence/nonexistence of a defect or specify a defect position with the semiconductor being made an object.

2. Description of the Related Art

In recent years, in an LSI (Large Scale Integrated Circuit) whose increases in minuteness and integration proceed, it becomes difficult to detect a disconnection defect (i.e., open failure) and analyze the defect of the LSI.

Conventional examples of defect analysis techniques detecting a disconnection failure of the LSI are disclosed in JP-A-10-10208 Gazette and JP-A-2001-141776 Gazette. In the technique described in the JP-A-10-10208 Gazette, an electric potential in a defect place is changed between an intermediate potential (intermediate voltage) and an electric potential (hereafter, L (Low) level) lower than the former as well as an electric potential (hereafter, H (High) level) higher than the former by irradiating an electron beam to an arbitrary disconnected wiring part and, by obtaining thereby a potential image in which only the disconnected wiring part or a circuit connected thereto is blinking, a failure place is specified. Further, in the technique described in the JP-A-2001-141776 Gazette, as to the application of the electric potential change, the electric potential change is generated not by, the irradiation of the electron beam but by an electromotive force generated by locally applying a magnetic field to a magnetic field generating head and, by obtaining this as the potential image, the existence/nonexistence of the defect is detected.

### SUMMARY OF THE INVENTION

In the above conventional examples, since an electron beam control device, an EB tester (electron beam tester) for obtaining a potential image and the like are used, a device for retaining the LSI to a vacuum state is demanded and thus the apparatus becomes large in size, and an apparatus cost corresponding thereto becomes necessary as well.

Whereupon, in order to specify the disconnection defect place by a simpler apparatus, for example, it is considered to perform the defect diagnosis by locally applying an electric field (magnetic field) to a surface of a semiconductor integrated circuit by using a probe and the like, thereby detecting a fluctuation of electric characteristics, such as power supply current, in the semiconductor integrated circuit at that time. However, in this technique, a position detection of a tip of the electric field (magnetic field) probe with respect to the LSI is difficult, and thus there is a problem that it is difficult to accurately perform a local application of the electric field (magnetic field) to an internal coordinate position of the LSI.

In the invention, in the above-mentioned method of performing the diagnosis of the defect by locally applying the electric field (magnetic field) to the surface of the semiconductor integrated circuit by using the probe and the like and thereby detecting the fluctuation of the electric characteristics, such as power supply current, in the semiconductor integrated circuit at that time, a precise application of a local electric field (magnetic field) to a coordinate position inside the LSI is made possible by providing a position reference for a tip of the electric field (magnetic field) probe and performing a positional alignment with respect to this reference prior to the diagnosis. By this, there is provided a defect diagnosis method for a semiconductor integrated circuit, which can be realized by a small and simple apparatus with respect to the large apparatus using the electron beam.

According to the invention, it becomes possible to perform the defect diagnosis of the semiconductor integrated circuit by a simpler analysis apparatus, and a precise confirmation of the defect place and a reduction in analysis time become possible.

### BRIEF DESCRIPTION OF THE DRAWINGS

FIG. 1 is a schematic diagram of a defect analysis apparatus according to the invention;

FIG. 2 is a disconnection defect schematic diagram of an inverter circuit;

FIG. 3 is a schematic diagram of a basic method of activating a defect place;

FIG. 4 is a schematic diagram of the defect analysis apparatus having no position reference of a probe;

FIG. 5 is a diagram showing an example in which a position reference pattern has been provided on an LSI package;

FIG. 6 is a diagram showing an example of a detection level of positional displacement (position offset) between the position reference pattern and the probe;

FIG. 7 is a diagram showing a constitution example in which a detection circuit for the position reference has been provided inside an LSI;

FIG. 8 is a diagram showing the constitution example in which the detection circuit for the position reference has been provided inside the LSI;

FIG. 9 is a diagram showing an example in which a circuit for positioning the probe with respect to the position reference has been disposed inside the LSI;

FIG. 10 is a diagram showing an example in which a height of the probe by using, inside the LSI, the circuit for positioning the probe with respect to the position reference; and

FIG. 11 is an explanatory diagram of a positioning flow with respect to the position reference of the probe.

### DETAILED DESCRIPTION OF THE INVENTION

Hereunder, it is explained about an embodiment of the invention by using the drawings.

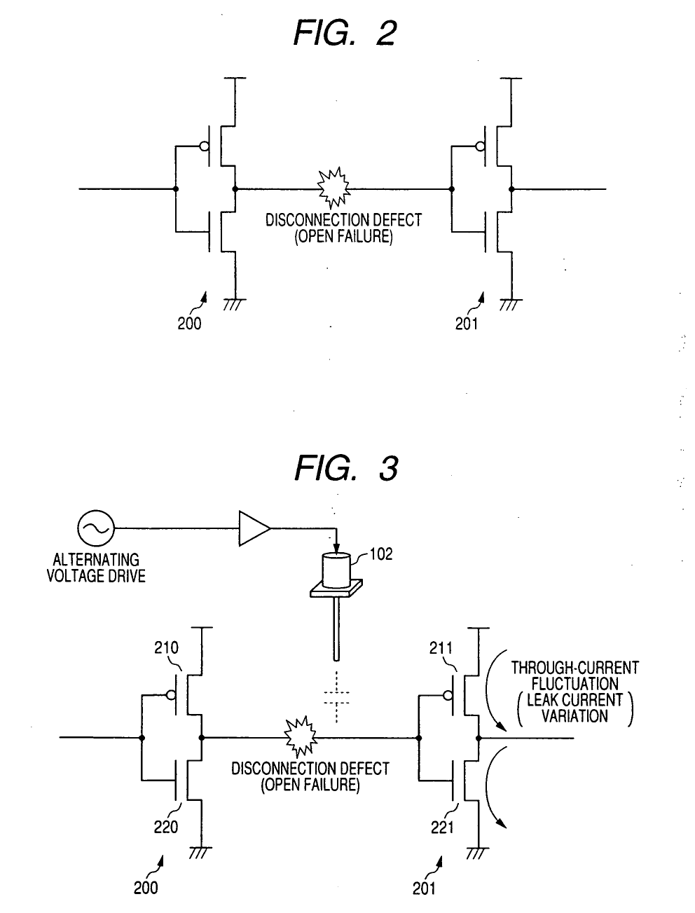

In FIG. 2, there is shown a defective example in a circuit between inverters 200, 201, each of which comprises a simplest CMOS (complementary metal-oxide semiconductor device) used in the semiconductor integrated circuit. It is supposed that a disconnection defect has occurred in a midway of a wiring leading from the inverter 200 in a preceding stage to the inverter 201 in a latter stage in the LSI. In order to detect this disconnection defect by a simple method, as shown in FIG. 3, an electric field probe 102 is positioned adjacently to an LSI surface, and an alternating voltage is applied. At this time, if the electric field probe 102 is sufficiently minute one, when a probe tip is located adjacently to the wiring in which the disconnection exists, a capacitive coupling between this probe 102 and the disconnected wiring becomes largest. This probe 102 is driven by the alternating voltage. The wiring adjacent to the probe undergoes an influence of the alternating voltage by the capacitve coupling with the probe 102. If there exists no disconnection in the wiring, the wiring is connected at a low impedance to a ground side or a power supply side by transistors (one pair of p-type 210 and n-type 220) in the preceding stage and, even if it undergoes the influence of the alternating voltage, no measurable electric potential change occurs in its electric potential. However, if there is the disconnection in the wiring, in a part following the disconnection place, it is not driven by the transistors 210, 220 in the preceding stage, and also transistors (one pair of p-type 211 and n-type 221) in the latter stage are merely connected to a gate input, and placed under a high impedance state with respect to a ground and a power supply. For this reason, the wiring following the disconnection place undergoes the influence of the alternating voltage and its electric potential fluctuates. This voltage fluctuation fluctuates a gate electric potential of an inverter 201 in the latter stage and, as a result, the transistors 211, 221 of the inverter 201 in the latter stage perform an incomplete switching operation in an unsaturated region, thereby bringing about a consumption current fluctuation. Although this consumption current fluctuation is minute one in comparison with a leak current of the whole LSI, since it synchronizes with a fluctuation frequency which is driving the electric field probe 102, it can be detected by using a lock-in amplifier (not shown in the drawing) and the like.

The above detection is performed while changing a position of the electric field probe 102 on the SLI surface. The fluctuation is not detected in a portion more adjacent to the preceding stage than the disconnection place, and the fluctuation is observed in a portion adjacent to the latter stage. Further, the fluctuation is detected only in a vicinity of the wiring where the disconnection exists and, if the probe becomes more distant from the wiring of an object, the fluctuation becomes not detected. For this treason, by mapping a position where the fluctuation detection has existed on the LSI surface while being corresponded to the fluctuation of the consumption current, a shape of the wiring which is under a floating state due to the disconnection becomes clear.

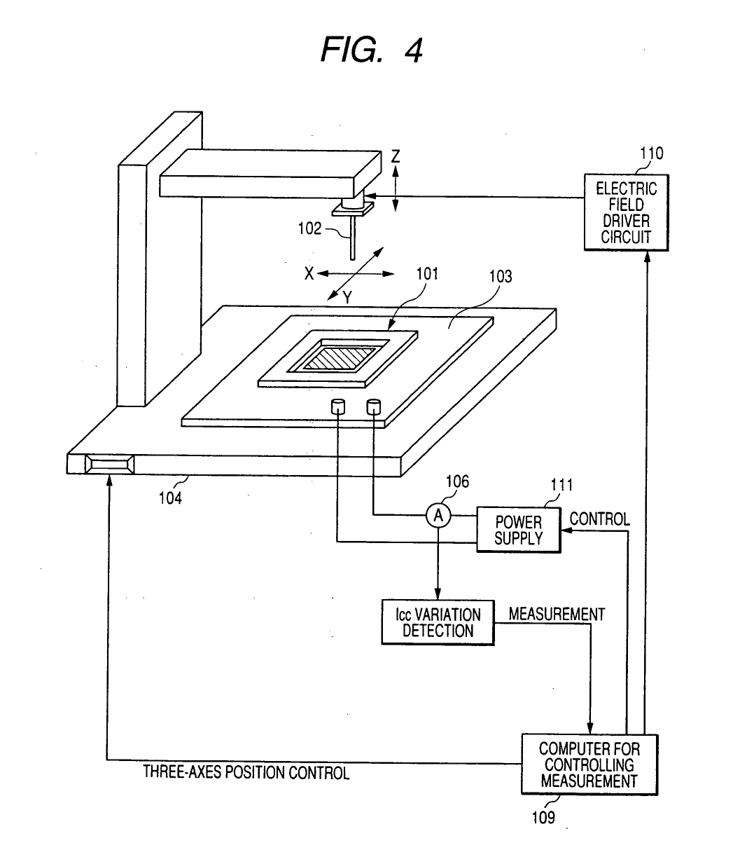

FIG. 4 is an example of a diagnosis apparatus diagnosing the semiconductor integrated circuit by the method mentioned above. The electric field probe 102 is mounted to a three-axes stage (triaxial stage) 104, and position-controlled in three directions of X, Y, Z. An LSI 101 of a diagnosis object is disposed just below the electric field probe 102 in the three-axes stage 104. A power is supplied from a power supply 111 to the LSI 101. A current measurement means 106 is connected to a power supply system and, by this, the fluctuation of the current is detected. The electric field probe 102 is driven by an electric field driver circuit 110. These are all controlled by a computer 109 for controlling measurement. However, under this mode, it is difficult to accurately control a tip position of the electric field probe 102 with respect to an internal coordinate of the LSI of the diagnosis object.

This is because there is not possessed a detecting mechanism accurately performing a position reference setting of the probe, which becomes indispensable for accurately coordinate-controlling the probe, and thus it is difficult to specify a precise position with respect to the LSI internal coordinate.

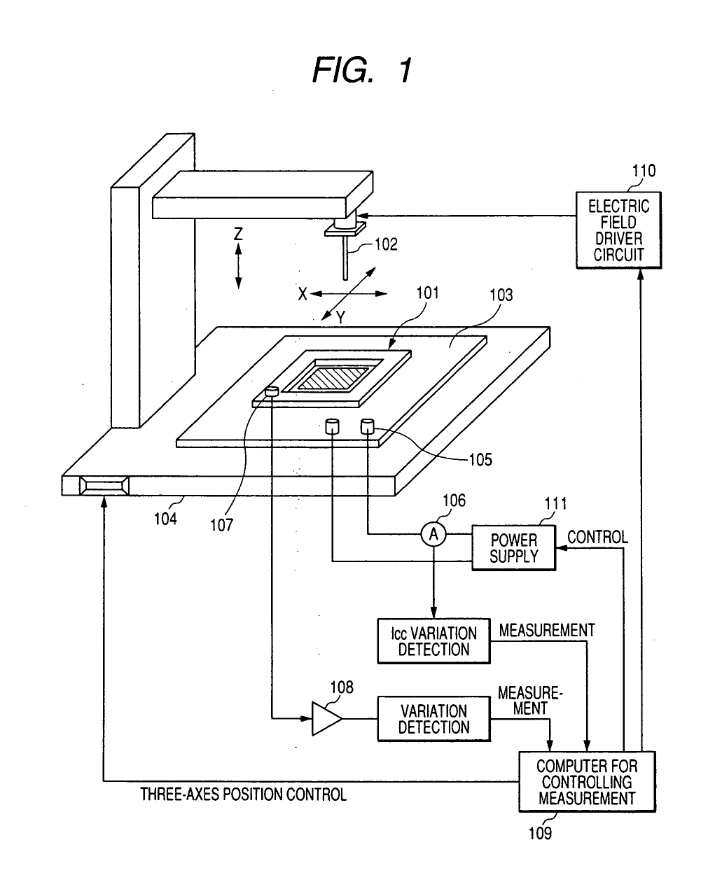

One constitution example solving this problem is shown in FIG. 1. FIG. 1 is a schematic diagram of a semiconductor electromagnetic field diagnosis analysis apparatus having a position detection device of the semiconductor integrated circuit, which is one example of the present embodiment. The analysis apparatus of the present embodiment possesses as its main constituents the probe 102, a substrate 103, the three-axes stage 104, substrate power supply terminals 105, a current measurement component 106, and a position reference 107. When an analysis is performed by the electromagnetic field diagnosis apparatus, the probe 102 is driven with respect to the analysis LSI 101 by an electric power supplied by the electric field driver circuit 110, thereby generating the electric field or the magnetic field. The generated electric field or magnetic field is locally irradiated to the LSI 101, and an electromotive force corresponding to an electric field or magnetic field strength is given to the wiring on the LSI 101. By this electromotive force, it is possible to vary an intermediate potential of an open gate, and a through-current (leak current) is generated by activating a gate circuit or a gate potential, so that it is possible to vary a power supply current. This power supply current variation is measured in the current measurement 106 through the substrate power supply terminals 105, and a linkage with a three-dimensional coordinate of the probe controlled by the computer 109 for controlling measurement is performed, thereby generating a diagnosis map of an analysis area. In order to realize a precise diagnosis, it becomes indispensable to accurately coordinate-control the probe, and thus it is demanded to accurately perform the position reference setting with respect to the probe before the diagnosis. For this demand, in the present embodiment, a weak probe position signal detected by the position reference 107 is amplified by an amplifier 108 and, in the measurement computer 109, the position reference of the probe is accurately detected by monitoring this signal, thereby accurately performing the coordinate control of the probe.

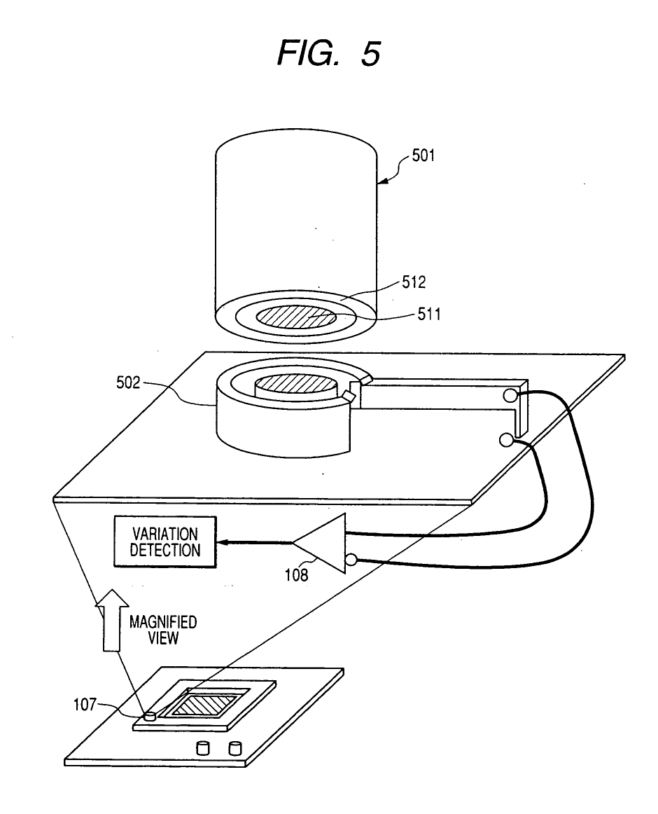

A matter becoming a key of this position control of a tip of the probe according to the invention is a positional alignment of the tip of the probe with respect to a reference position. In FIG. 5 of the embodiment, there is shown an enlarged diagram of the position reference 107. In the embodiment, there is possessed a position reference pattern 502 having the same diameter dimensions as an inner conductor 511 and an outer conductor 512 of a coaxial probe 501, and a differential potential of the above pattern is accurately measured through a differential amplifier 108.

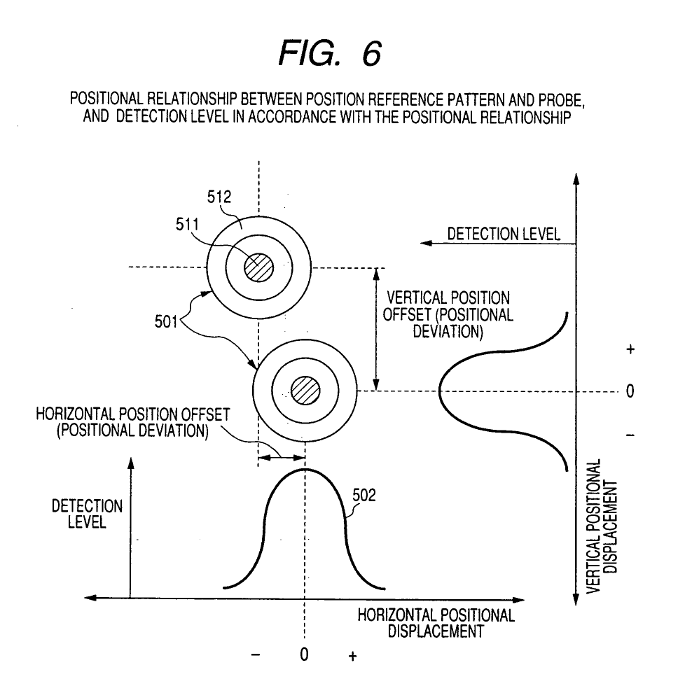

A measurement signal measured by this position reference 107 is shown in the embodiment of FIG. 6. In the position reference 107, by a relationship between the position reference pattern and the probe position, there is shown an output characteristic that a detection level becomes maximum when the both coincide with the same coordinate with respect to coordinates of an x-axis direction and a y-axis direction, and the detection level axisymmetrically attenuates from a center value in compliance with a positional displacement amount. Form the above output characteristic, the relationship between the position reference pattern and the probe position is judged in a real time and, by searching for a point at which the detection level becomes maximum, an accurate position reference setting with respect to the probe is realized.

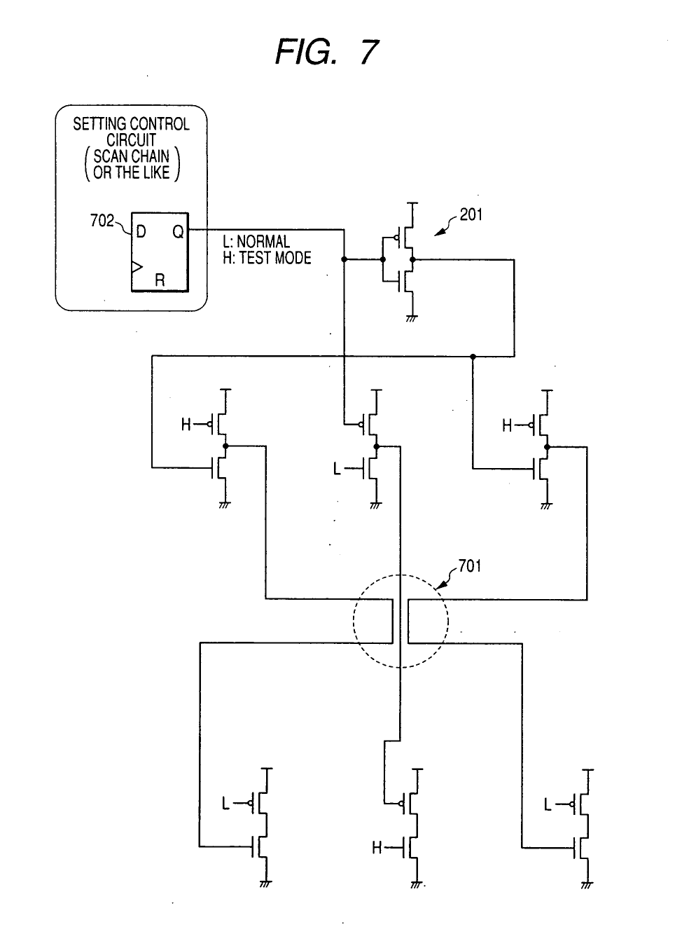

Further, in FIG. 7 of the embodiment, there is shown a circuit diagram in a case where a position reference pattern function is constituted in the LSI by a gate circuit. A circuit with this position reference pattern function, which is controlled by a setting control circuit 702 such as scan chain, does not perform a toggle operation in a normal mode, and each node in the circuit concerned is fixed to an H or L level. In a case where this circuit is used as the position reference, the circuit is introduced into a test mode by the scan chain and the like. In the test mode, in a case where there is the alternating electric field with respect to a position reference wiring 701 inside a chip in the drawing, since each circuit of the inverters in the latter stage performs an incomplete toggle operation due to this potential fluctuation of the wiring, by detecting the fluctuation of the power supply current (I_{CC} variation), it is possible to detect the fact that the probe is located on the position reference wiring 701.

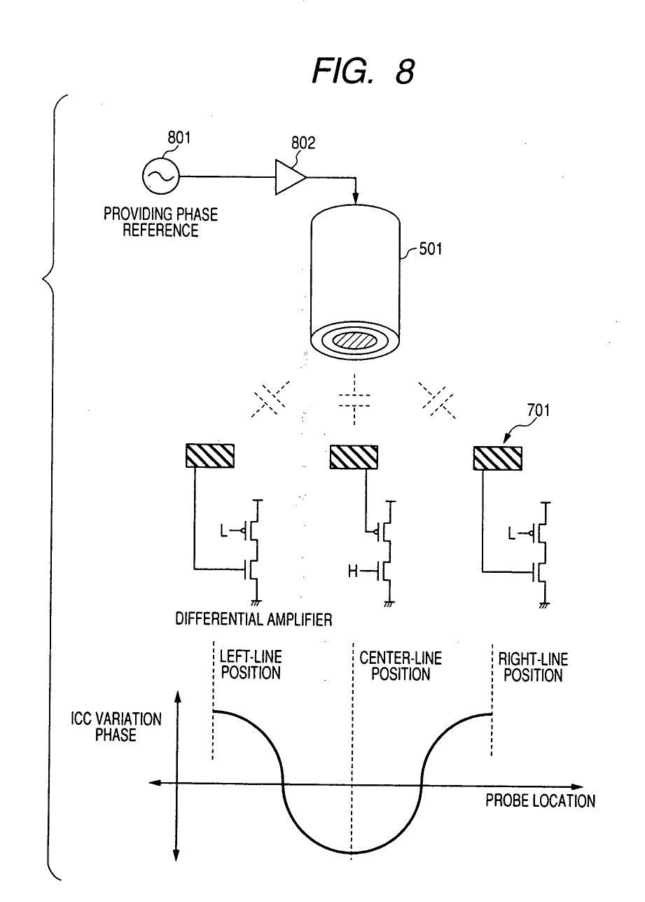

An operation at this time is shown in FIG. 8. The coaxial probe 501 is driven by an alternating voltage supplied from a power supply 801 through an amplifier 802. By this, the potential fluctuation of the position reference wiring 701 inside the chip is generated. In FIG. 8, there are shown a section and each positioning of the wiring. In this position reference detection circuit, it is juxtaposed such that a phase of the current fluctuation becomes reverse in three rows. That is, it is disposed in such rows that the phase of the current fluctuation is reversed between a case where a nearest end position of the probe is biased to any of both sides of the three rows and a case where it is located just in a center of the three rows. By utilizing this, an accurate position setting of the probe is performed.

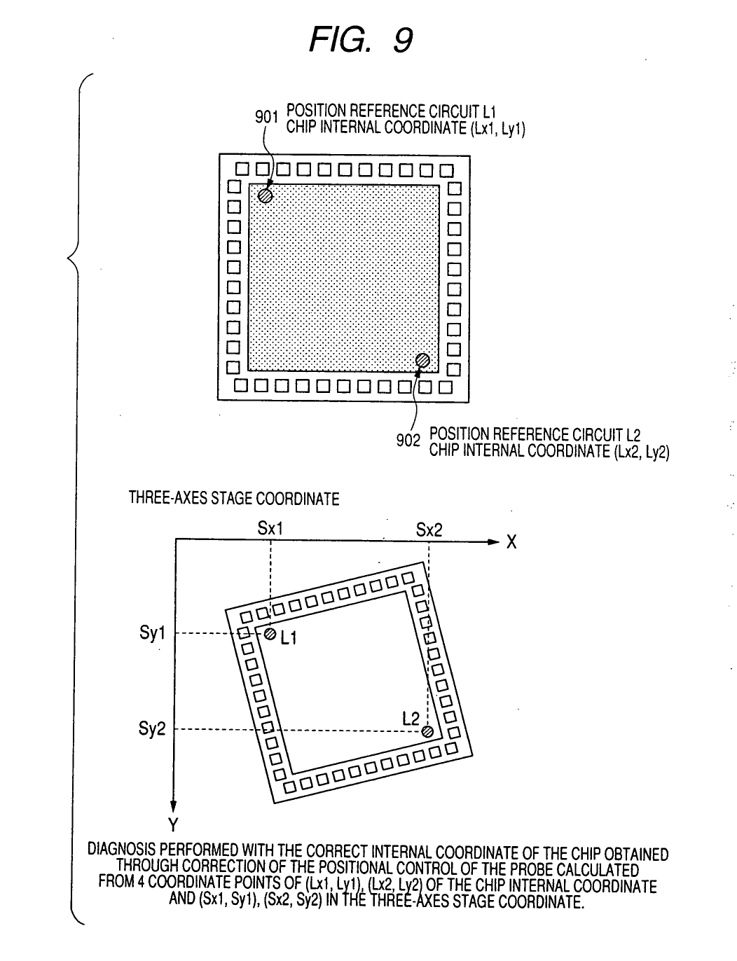

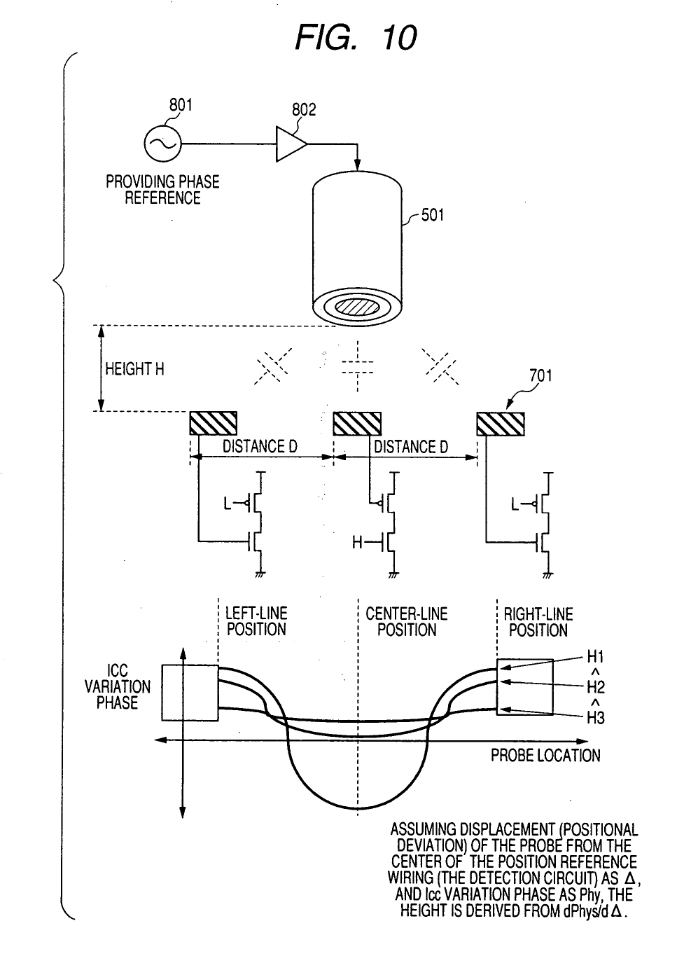

In FIG. 9, there is shown an example in which position reference circuits 901, 902 have been provided in plural places of al least two places inside the LSI. The position setting of the probe is performed by using these position reference circuits in the two places. A position of the probe with respect to the LSI (diagnosis object) is controlled in accordance with a three-axes stage coordinate. When axes of a chip internal coordinate of the LSI are slanting with respect to coordinate axes of the three-axes stage, the position of the probe thus controlled is corrected in accordance with the chip internal coordinate of the LSI by a calculation using a point L1 (Lx1, Ly1) of the chip internal coordinate showing the position reference circuit 901 of the LSI, a point (Sx1, Sy1) of the three-axes stage coordinate, a point L2 (Lx2, Ly2) of the chip internal coordinate showing the position reference circuit 902 of the LSI concerned, and a point (Sx2, Sy2) of the three-axes stage coordinate. After the correction by such a calculation, the point of the chip internal coordinate (LSI coordinate) showing the diagnosis object place of the LSI is precisely converted into a point of a control coordinate of the three-axes stage, which corresponds to the former point. Accordingly, it becomes possible to accurately move the probe to the diagnosis object place of the LSI, and precisely and locally apply the electric field (magnetic field) to the place concerned.

Further, in FIG. 10, there is shown the fact that the above position reference circuit can be utilized also in setting a height of the probe. That is, if the probe height is high and thus separated from the LSI surface, a phase change of the power supply current (consumption current I_{CC}) when a probe position has been swung left and right with respect to the LSI becomes difficult to recognize because the three position reference circuits provided in the LSI concerned negate the phase change. On the other hand, in a case where the probe is sufficiently adjacent to the LSI surface, if the probe position is swung left and right with respect to the LSI, a phase of the current fluctuation concerned is reversed in compliance with the position of the probe with respect to the LSI (position reference circuit). By this, it becomes possible to derive the height of the probe from a probe displacement amount from a center position of any of the three position reference circuits (detection circuits) and a change amount of the above phase of the current.

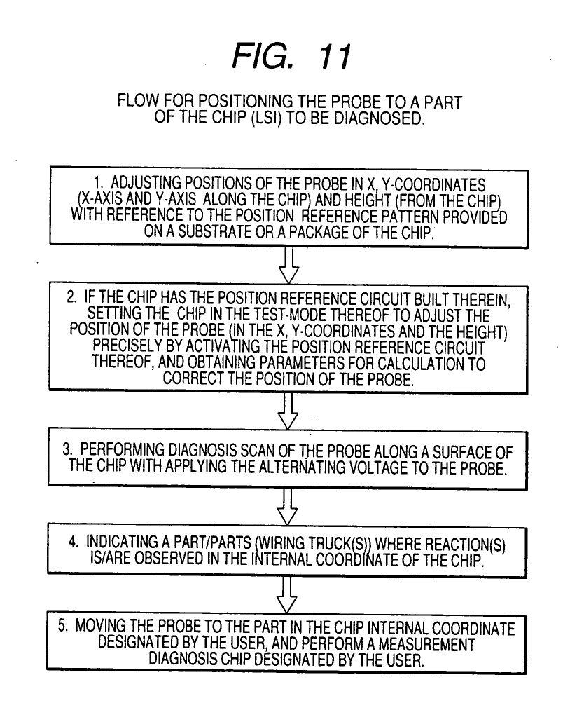

In FIG. 11, there is shown one example of position-aligning processes of the probe with respect to the LSI (chip) when the LSI is evaluated by the above-mentioned defect diagnosis method for the semiconductor integrated circuit according to the invention. By these series of processes, it becomes possible not only to specify the defect place inside the chip but also to detailedly analyze a defect state in the defect place by locally applying the electric field or the magnetic field to the defect place.

Not limited to the concrete means explained above, by performing the diagnosis after performing the reference alignment of the probe position with respect to the LSI internal coordinate prior to the diagnosis of the LSI, a precise confirmation of the defect place with respect to the LSI internal coordinate can be realized.

1. A defect diagnosis method for a semiconductor integrated circuit, which diagnoses an existence/nonexistence of a defect or a defect place in a semiconductor by measuring a fluctuation of electric characteristics, such as consumption current, of the semiconductor under a state that an electric field or a magnetic field has been applied to the semiconductor,
wherein a diagnosis can be performed by applying the electric field or the magnetic field to a precise internal coordinate position of the semiconductor of a diagnosis object by providing a position reference of an electric field application end for applying the electric field or a magnetic field application end for applying the magnetic field and performing the diagnosis of the semiconductor after aligning a position of the electric field application end or the magnetic field application end to a position complying with the position reference.

2. A defect diagnosis method for a semiconductor integrated circuit according to claim 1, wherein a detection means for the electric field or the magnetic field is provided in the position reference, and a positional alignment of the electric field application end for applying the electric field or the magnetic field application end for applying the magnetic field with respect to the position reference is performed by using a detection signal in the detection means.

3. A defect diagnosis method for a semiconductor integrated circuit according to claim 1, wherein an optical approach detection means is provided in the position reference, and a positional alignment of the electric field application end for applying the electric field or the magnetic field application end for applying the magnetic field with respect to the position reference is performed by using a detection signal in the detection means.

4. A defect diagnosis apparatus for a semiconductor integrated circuit, wherein a defect position of a semiconductor is detected by using a defect diagnosis method according to claim 1.

5. A defect diagnosis method for a semiconductor integrated circuit, comprising a detecting circuit wherein electric characteristics, such as consumption current, fluctuate by an application of an electric field or a magnetic filed is provided, and a positional alignment of an electric field application end for applying the electric field or a magnetic field application end for applying the magnetic field is performed with the detecting circuit being made a position reference.
